(19) United States
(12) Patent Application Publication
(10) Pub. No.: US 2025/0366021 A1
(43) Pub. Date: Nov. 27, 2025

(54) PDSOI TRANSISTOR AND METHOD FOR FABRICATING SAME

(71) Applicant: Hangzhou HFC Semiconductor Co., Hangzhou (CN)

(72) Inventors: Pengpeng WANG, Hangzhou (CN); Yongsheng YANG, Shanghai (CN); Haijiang YUAN, Shanghai (CN); Chungchiang LIN, Hangzhou (CN)

(21) Appl. No.: 18/733,057

(22) Filed: Jun. 4, 2024

(30) Foreign Application Priority Data
May 24, 2024 (CN) 202410650174.6

(51) Int. Cl. H01L 29/78; H01L 21/311; H01L 21/3115; H01L 21/762; H01L 29/66

(52) U.S. Cl. CPC H10D 30/637; H01L 21/31144; H01L 21/31155; H01L 21/76243; H10D 30/0227

(57) ABSTRACT

A partially depleted silicon-on-insulator (PDSOI) transistor and a method for fabricating the PDSOI transistor are disclosed. The PDSOI transistor includes: an SOI substrate including a bottom silicon layer, a buried oxide layer formed on the bottom silicon layer and a top silicon layer formed on the buried oxide layer, the top silicon layer formed therein with a well region; a gate structure formed on the SOI substrate; and a source and a drain, which are located in the well region on opposite sides of the gate structure. The source is formed by epitaxy, and at least a portion of the source is of the same conductivity type as the well region.

### CROSS-REFERENCE TO RELATED APPLICATION

This application claims the priority of Chinese patent application number 202410650174.6, filed on May 24, 2024 and entitled “PDSOI TRANSISTOR AND METHOD FOR FABRICATING SAME”, the entire contents of which are incorporated herein by reference.

### TECHNICAL FIELD

The present invention relates to the field of semiconductor technology, and in particular, to a partially depleted silicon-on-insulator (PDSOI) transistor and a method for fabricating the PDSOI transistor.

### BACKGROUND

Silicon-on-insulator (SOI) is a type of silicon material with a special structure. SOI technology has been vastly investigated in various aspects, such as materials, devices and integrated circuits (IC) fabrication techniques. As this technology is capable of complete dielectric isolation, it provides a variety of advantages such as high reliability, a fast speed, low power consumption and a high degree of integration.

The physical properties of an SOI transistor are closely related to the thickness of its top silicon layer. SOI transistors can be categorized into partially depleted (PD) transistors and fully depleted (FD) transistors, by the type of their top silicon layer.

Although PDSOI transistors are more popular nowadays, they are associated with a particular problem, known as the floating body effect (FBE). This issue arises due to a partially depleted active body region of the PDSOI transistors, as a result, the active body region floats, and charge carriers created by collisional ionization cannot rapidly migrate away. This may cause a range of issues with such devices, such as threshold voltage shifting, parasitic bipolar transistor action, the kink effect, reduced output resistance in the saturation region and transient changes in the drain current. Consequently, they may suffer from a lower gain, noise overshoot, instable operation, a reduced source-drain breakdown voltage, single transistor latch-up, a considerable leakage current and increased power consumption. All these place limitations on the development of PDSOI transistors and circuits.

### SUMMARY OF THE INVENTION

It is an object of the present invention to provide a PDSOI transistor and a method for fabricating the transistor, which overcome the floating body effect problem associated with conventional PDSOI transistors.

To this end, the present invention provides a PDSOI transistor, which comprises:
an SOI substrate comprising a bottom silicon layer, a buried oxide layer formed on the bottom silicon layer and a top silicon layer formed on the buried oxide layer, a well region formed in the top silicon layer;
a gate structure formed on the SOI substrate; and
a source and a drain, wherein the source and the drain are located in the well region on opposite sides of the gate structure, wherein the source is formed by epitaxy, and wherein at least a portion of the source has the same conductivity type as the well region.

The present invention further provides a method for fabricating a PDSOI transistor. The method comprises:

providing an SOI substrate comprising a bottom silicon layer, a buried oxide layer formed on the bottom silicon layer and a top silicon layer formed on the buried oxide layer, wherein at least one well region is formed in the top silicon layer;
forming at least one gate structure on the SOI substrate; and
forming at least one source and at least one drain in the SOI substrate by epitaxy, wherein the source and the drain are located in the well region on opposite sides of the gate structure, and wherein at least a portion of the source is of the same conductivity type as the well region.

In the PDSOI transistor and method of the present invention, the source is formed by epitaxy, and at least a portion of the source is of the same conductivity type as the well region. With this arrangement, electric charge can be conducted away from the body region through the source, avoiding the otherwise possible floating body effect (FBE) and imparting improved quality and reliability to the PDSOI transistor.

### BRIEF DESCRIPTION OF THE DRAWINGS

FIGS. 1 to 6 show schematic cross-sectional views of intermediate structures resulting from process steps in a method for fabricating a PDSOI transistor according to a first embodiment of the present invention.

FIGS. 7 to 11 show schematic cross-sectional views of intermediate structures resulting from process steps in a method for fabricating a PDSOI transistor according to a second embodiment of the present invention.

### LIST OF REFERENCE NUMERALS

100—SOI substrate; 101—bottom silicon layer; 102—buried oxide layer; 103—top silicon layer; 1030—well region; 1031—first well region; 1032—second well region; 110—isolation structure; 120—gate structure; 121—gate dielectric layer; 122—conductive layer; 123—TiN layer; 130—lightly doped source region; 1300—first lightly doped source region; 1301—second lightly doped source region; 131—lightly doped drain region; 1310—first lightly doped drain region; 1311—second lightly doped drain region; 140—spacer; 150—first patterned mask layer; 160, 160A, 160B, 160C—first opening; 170, 170A, 170B, 170C—first epitaxial structure; 180—second patterned mask layer; 190, 190A, 190B, 190C—second opening; 200, 200A, 200B, 200C—second epitaxial structure; 210—source; 211—first source; 212—second source; 2100—primary source; 2101—secondary source; 2110—first primary source; 2111—first secondary source; 2120—second primary source; 2121—second secondary source; 220—drain; 221—first drain; 222—second drain; 230—interlayer dielectric layer; 240—gate contact; 241—source contact; 242—drain contact; 300—first patterned mask layer; 310, 310A, 310B—first opening; 320, 320A, 320B—first epitaxial structure; 330—second patterned mask layer; 340, 340A, 340B—second opening; 350, 350A, 350B—second epitaxial structure; 360—source; 361—first source; 362—second source; 3600—primary source; 3610—first primary source; 3620—second primary source; 370—drain; 371—first drain; 372—second drain; 380—interlayer dielectric layer; 390—gate contact; 391—source contact; 392—drain contact; L1—first distance; L2—second distance; L3—first distance; L4—second distance.

### DETAILED DESCRIPTION

### Embodiment 1

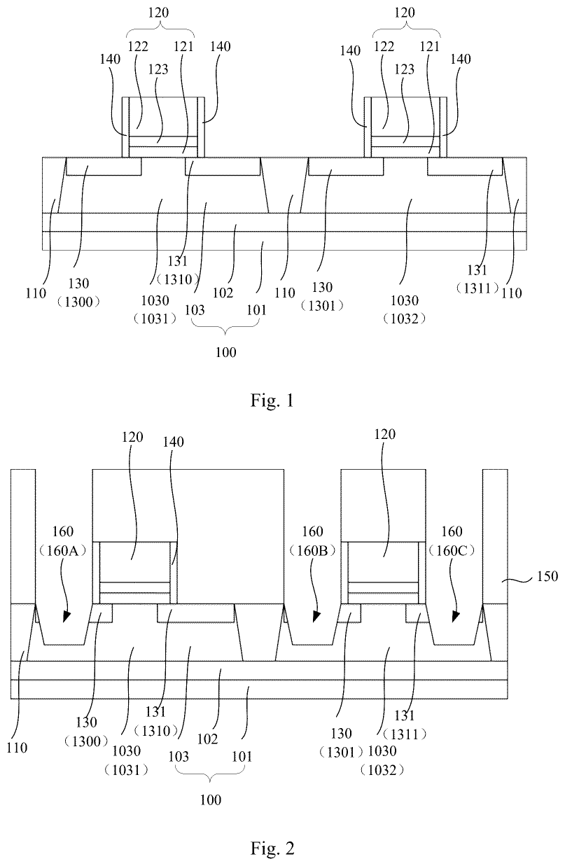

FIGS. 1 to 6 show schematic cross-sectional views of intermediate structures resulting from process steps in a method for fabricating a PDSOI transistor according to Embodiment 1 of the present invention.

As shown in FIG. 1, an SOI substrate 100 is provided. The SOI substrate 100 includes a bottom silicon layer 101, a buried oxide layer 102 formed on the bottom silicon layer 101 and a top silicon layer 103 formed on the buried oxide layer 102.

Next, isolation structures 110 are formed in the SOI substrate 100. The isolation structures 110 extend from a surface of the top silicon layer 103 to a top surface of the buried oxide layer 102. The isolation structures 110 may be made of, for example, silicon oxide or the like. In the figures, three of the isolation structures 110 are schematically shown to form two device regions.

With continued reference to FIG. 1, an ion implantation process is then performed on the SOI substrate 100 to form well regions 1030 in the top silicon layer 103. According to embodiments of the present application, two well regions 1030 are formed in the two device regions and referred to herein respectively as a first well region 1031 and a second well region 1032. The two well regions 1030 may be of the same conductivity type, or of different conductivity types. For example, the two well regions 1030 may be both P-wells or N-wells. Alternatively, one of them may be an N-well, and the other may be a P-well. In the Embodiment 1, the first well region 1031 is a P-well, and the second well region 1032 is an N-well.

Subsequently, gate structures 120 are formed on the SOI substrate 100. The gate structure 120 includes a gate dielectric layer 121 and a conductive layer 122 formed on the gate dielectric layer 121. The gate dielectric layer 121 may be a high dielectric constant (k>3.9) material, or a low dielectric constant (k≤3.9) material. The conductive layer 122 may be polysilicon. Between the gate dielectric layer 121 and the conductive layer 122, there may be formed a titanium nitride (TiN) layer 123, which can enhance the quality and reliability of the resulting gate structure 120.

With continued reference to FIG. 1, ion implantation processes are performed on the well regions 1030 to form lightly doped source regions 130 and lightly doped drain regions 131 in the well regions 1030. The lightly doped source regions 130 and the lightly doped drain regions 131 extend from the well regions 1030 under the gate structures 120 to the well regions 1030 on opposite sides of the gate structures 120. N-type ions may be implanted into the first well region 1031 to form a first lightly doped source region 1300 and a first lightly doped drain region 1310 in the first well region 1031, and P-type ions may be implanted into the second well region 1032 to form a second lightly doped source region 1301 and a second lightly doped drain region 1311 in the second well region 1032.

According to embodiments of the present application, ions may be implanted at a dose greater than or equal to 1.0 e15 cm⁻² to form the lightly doped source regions 130 and the lightly doped drain regions 131. In Embodiment 1, ions may be implanted at a relatively high dose to form the lightly doped source regions 130 and the lightly doped drain regions 131 to allow the resulting PDSOI transistors to have improved electrical conduction properties.

Afterwards, spacers 140 are formed on opposite sidewalls of the gate structures 120. The spacers 140 may be either monolayer structures or multilayer layers. For example, the spacers 140 may include only one silicon oxide layer, or may include a silicon oxide layer and a silicon nitride layer covering the silicon oxide layer.

Referring to FIG. 2, according to embodiments of the present application, a first patterned mask layer 150 is then formed over the SOI substrate 100. The first patterned mask layer 150 covers the gate structures 120 and a portion of the SOI substrate 100, leaving the remaining portion of the SOI substrate 100 being exposed.

The exposed portion of the SOI substrate 100 is etched to form first openings 160 in the SOI substrate 100. The first openings 160 extend from surface of the well region 1030 into the well region 1030. In Embodiment 1, one first opening 160 is formed in the first well region 1031, and two first openings 160 are formed in the second well region 1032, and these first openings 160 are referred to herein respectively as a first opening 160A, a first opening 160B and a first opening 160C. According to embodiments of the present application, each of the first opening 160A, the first opening 160B and the first opening 160C is adjacent to and connected with the spacer 140 on the gate structure 120.

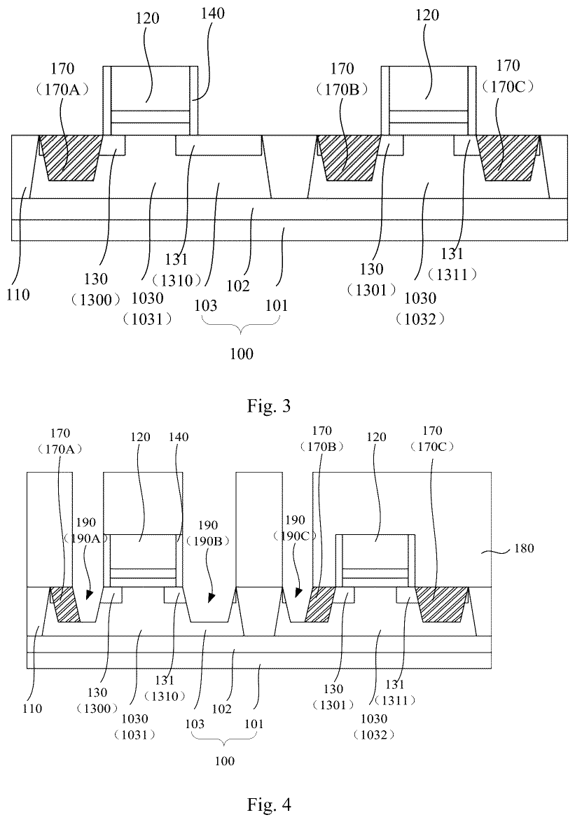

Next, as shown in FIG. 3, a first epitaxy process is carried out to form first epitaxial structures 170 in the first openings 160. Specifically, a first epitaxial structure 170A is formed in the first opening 160A, a first epitaxial structure 170B is formed in the first opening 160B and a first epitaxial structure 170C is formed in the first opening 160C. According to embodiments of the present application, concurrently with the first epitaxy process, a P-type doping process is performed so that the resulting first epitaxial structures 170 are of the P conductivity type. The P-type first epitaxial structures 170 have a dopant concentration higher than a concentration of the P-type first well region 1031. Preferably, the first epitaxial structures 170 contain conductive ions at a concentration greater than or equal to 1.0 e20 cm⁻³. The first patterned mask layer 150 is then stripped away.

Referring to FIG. 4, according to embodiments of the present application, a second patterned mask layer 180 is then formed over the SOI substrate 100. The second patterned mask layer 180 covers the gate structures 120, a portion of the first epitaxial structure 170 and a portion of the SOI substrate 100, leaving the remaining portion of the first epitaxial structure 170 and remaining portion of the SOI substrate 100 being exposed.

The exposed first epitaxial structures 170 and SOI substrate 100 are etched to form second openings 190. Specifically, a second opening 190A is formed in the first epitaxial structure 170A, which extends from a surface of the first epitaxial structure 170A to the bottom thereof, exposing the first well region 1031. In Embodiment 1, the second opening 190A is closer to the (corresponding) gate structure 120 than the remaining portion of the first epitaxial structure 170A. A second opening 190B is formed in the first well region 1031, which extends from the surface of the first well region 1031 into the first well region 1031. A second opening 190C is formed in the first epitaxial structure 170B, which extends from a surface of the first epitaxial structure 170B to the bottom thereof, exposing the second well region 1032. In Embodiment 1, the second opening 190C is farther away from the (corresponding) gate structure 120 (the right-hand one in FIG. 4) than the first epitaxial structure 170B.

In other embodiments of the present application, the second opening 190A and the second opening 190C may also be formed by etching the well regions 1030. In this case, the first opening 160A and the first opening 160C may be so formed as to each have a smaller cross-sectional width so that the well regions 1030 are large enough for the second opening 190A and the second opening 190C to be formed therein.

According to embodiments of the present application, the second openings 190 have the same depth as the first openings 160. Of course, there may be tolerances among the first openings 160, among the second openings 190, and among the first opening 160 and second opening 190. For example, there may be a depth difference between the first and second openings, which is less than 10% or the like of a predetermined depth. The first openings 160 and the second openings 190 are each spaced at a certain distance from the top surface of the buried oxide layer 102.

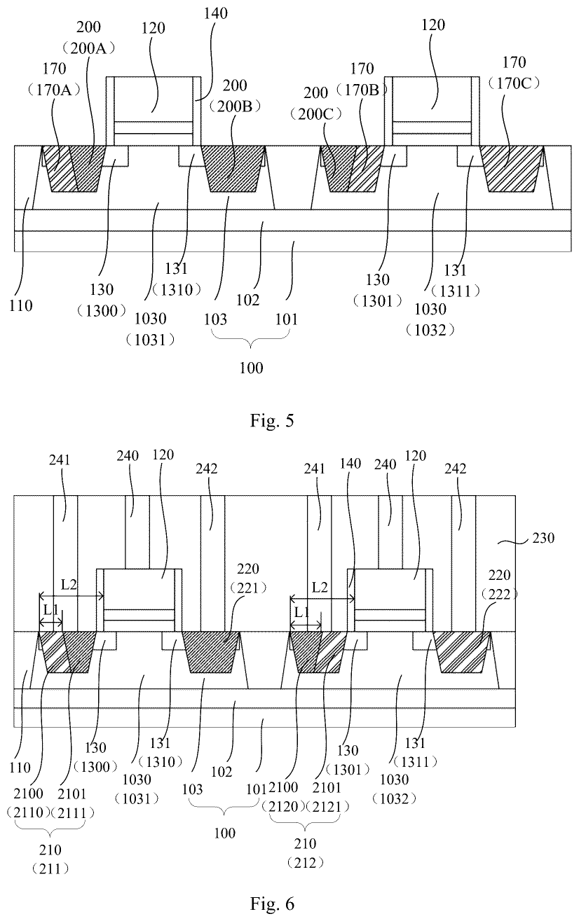

After that, as shown in FIG. 5, a second epitaxy process is performed to form second epitaxial structures 200 in the second openings 190. Specifically, a second epitaxial structure 200A is formed in the second opening 190A, a second epitaxial structure 200B is formed in the second opening 190B, and a second epitaxial structure 200C is formed in the second opening 190C. According to embodiments of the present application, concurrently with the second epitaxy process, an N-type doping process is performed so that the resulting second epitaxial structures 200 are of the N conductivity type. The N-type second epitaxial structures 200 have a dopant concentration higher than a dopant concentration of the N-type second well region 1032. Preferably, the second epitaxial structures 200 contain conductive ions at a concentration greater than or equal to 1.0 e20 cm⁻³. The second patterned mask layer 180 is then stripped away.

Next, as shown in FIG. 6, an annealing process is performed on the first epitaxial structures 170 and the second epitaxial structures 200 to form sources 210 and drains 220 in the well regions 1030. According to embodiments of the present application, the source 210 includes two portions, referred to herein respectively as a primary source 2100 and a secondary source 2101. The primary source 2100 and the secondary source 2101 are located side by side along the extension of the SOI substrate 100, and the primary source 2100 is farther away from the (corresponding) gate structure 120 than the secondary source 2101.

The conductivity type of the drain 220 differs from the conductivity type of the (corresponding) well region 1030, and at least a portion of the source 210 has the same conductivity type as the (corresponding) well region 1030. According to embodiments of the present application, the primary source 2100 has the same conductivity type as the (corresponding) well region 1030, and the primary source 2100 has a higher dopant concentration than the (corresponding) well region 1030, and the conductivity type of the secondary source 2101 is different from the conductivity type of the (corresponding) well region 1030.

With continued reference to FIG. 6, in Embodiment 1, as a result of the annealing process performed on the first epitaxial structures 170 and the second epitaxial structures 200, a first source 211 and a first drain 221 are formed in the first well region 1031, and a second source 212 and a second drain 222 are formed in the second well region 1032. The first source 211 includes a P-type first primary source 2110 and an N-type first secondary source 2111. The second source 212 includes an N-type second primary source 2120 and a P-type second secondary source 2121.

According to embodiments of the present application, a first side of the primary source 2100 is spaced from a second side of the primary source 2100 at a first distance L1, and is spaced from a third side of the (corresponding) gate structure 120 at a second distance L2. Preferably, the first distance L1 is less than or equal to 0.5 times the second distance L2. The first side is a side of the primary source 2100 far away from the (corresponding) gate structure 120, while the second side is a side of primary source 2100 proximal to the (corresponding) gate structure 120. The third side is a side of the gate structure 120 proximal to the corresponding source 210. With this arrangement, not only good performance of the resulting transistors can be ensured, but electric charge can also be conducted away from their body regions through the sources 210, avoiding the otherwise possible floating body effect (FBE). Thus, PDSOI transistors with improved quality and reliability can be obtained.

With continued reference to FIG. 6, an interlayer dielectric layer 230 is further formed over the SOI substrate 100, which covers the SOI substrate 100 and the gate structures 120. Gate contacts 240, source contacts 241 and drain contacts 242 are then formed in the interlayer dielectric layer 230. The gate contacts 240 are connected to the gate structures 120, the source contacts 241 are connected to the sources 210, and the drain contacts 242 are connected to the drains 220.

In embodiments of the present application, there is also provided a corresponding PDSOI transistor. As shown in FIG. 6, the PDSOI transistor includes: an SOI substrate 100 including a bottom silicon layer 101, a buried oxide layer 102 formed on the bottom silicon layer 101 and a top silicon layer 103 formed on the buried oxide layer 102, a well region 1030 is formed in the top silicon layer 103; a gate structure 120 formed on the SOI substrate 100; and a source 210 and a drain 220, which are located in the well region 1030 on opposite sides of the gate structure 120, the source 210 formed by epitaxy, at least a portion of the source 210 having the same conductivity type as the well region 1030.

The source 210 includes a primary source 2100 and a secondary source 2101, which are located side by side along the extending direction of the SOI substrate 100. The secondary source 2101 is closer to the gate structure 120 than the primary source 2100. The primary source 2100 has the same conductivity type as the well region 1030, and the primary source 2100 has a higher dopant concentration than (corresponding) well region 1030. The conductivity type of the secondary source 2101 differs from the conductivity type of the well region 1030. The source 210 contains conductive ions at a concentration greater than or equal to 1.0 e20 cm⁻³.

The PDSOI transistor further includes a lightly doped source region 130 and a lightly doped drain region 131, each of which extends from the well region1 030 under the gate structure 120 to the well region 1030 beside the gate structure 120. The lightly doped source region 130 and the lightly doped drain region 131 are formed through ion implantation at a dose greater than or equal to 1.0 e15 cm⁻².

The PDSOI transistor further includes: an interlayer dielectric layer 230 which covers both the SOI substrate 100 and the gate structure 120; and a gate contact 240, a source contact 241 and a drain contact 242 formed in the interlayer dielectric layer 230, the gate contact 240 connected to the gate structure 120, the source contact 241 connected to the source 210, the drain contact 242 connected to the drain 220.

With this arrangement, electric charge can be conducted away from the body region through the source 210, avoiding the otherwise possible floating body effect (FBE) and imparting improved quality and reliability to the PDSOI transistor.

### Embodiment 2

Embodiment 2 differs from the Embodiment 1 in that: in Embodiment 1, a portion of the source is of the same conductivity type as the corresponding well region, however, in Embodiment 2 of the present invention, the entirety source is of the same conductivity type as the corresponding well region. That is, source of Embodiment 2 consists of only the primary source.

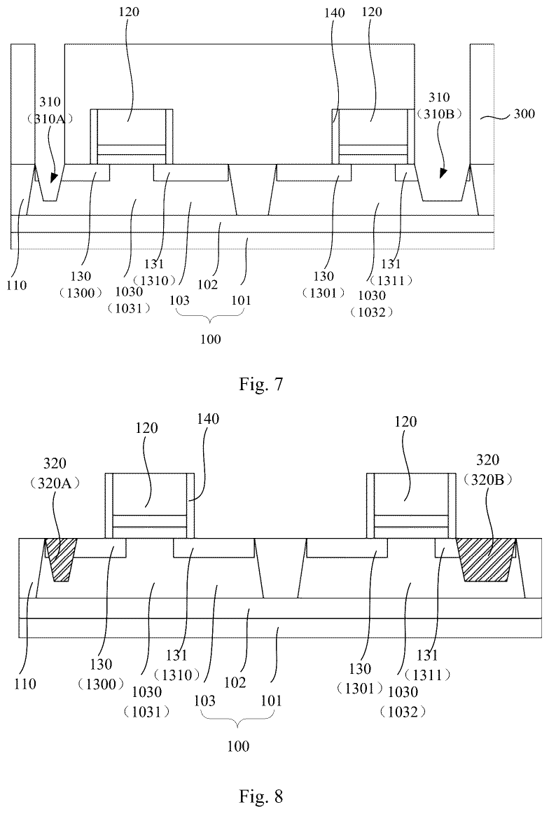

In particular, reference is made to FIGS. 7 to 11, which show schematic cross-sectional views of intermediate structures resulting from process steps in a method for fabricating a PDSOI transistor according to the second embodiment of the present invention. In Embodiment 2, the same SOI substrate as in the Embodiment 1 may be provided, and accordingly, reference is made to FIG. 1.

First of all, as shown in FIG. 1, an SOI substrate 100 is provided, which includes a bottom silicon layer 101, a buried oxide layer 102 formed on the bottom silicon layer 101 and a top silicon layer 103 formed on the buried oxide layer 102. Next, isolation structures 110 are formed in the SOI substrate 100, and an ion implantation process is performed on the SOI substrate 100 to form well regions 1030 in the top silicon layer 103. In Embodiment 2, a first well region 1031 and a second well region 1032 are formed as a result of the ion implantation process. The first well region 1031 is a P-well, and the second well region 1032 is an N-well.

Additionally, gate structures 120 are formed on the SOI substrate 100, and an ion implantation process is performed on the well regions 1030 to form lightly doped source regions 130 and lightly doped drain regions 131 in the well regions 1030. Spacers 140 are then formed on opposite side walls of the gate structures 120.

Next, referring to FIG. 7, according to embodiments of the present application, a first patterned mask layer 300 is formed over the SOI substrate 100. The first patterned mask layer 300 covers the gate structures 120 and a portion of the SOI substrate 100, leaving a remaining portion of the SOI substrate 100 being exposed.

The exposed SOI substrate 100 is etched to form first openings 310 therein, the first opening 310 extends from a surface of the well region 1030 into the well region 1030. In Embodiment 2, one first opening 310 is formed in the first well region 1031, another first opening 310 is formed in the second well region 1032, and these first openings 310 are referred to herein respectively as a first opening 310A and a first opening 310B. According to embodiments of the present application, the first opening 310A is spaced apart from the spacer 140 on the corresponding gate structure 120, and the first opening 310B is adjacent to and connected with the spacer 140 on the corresponding gate structure 120.

Subsequently, as shown in FIG. 8, a first epitaxy process is performed to form first epitaxial structures 320 in the first openings 310. Specifically, a first epitaxial structure 320A is formed in the first opening 310A, and a first epitaxial structure 320B in the first opening 310B. According to embodiments of the present application, concurrently with the first epitaxy process, a P-type doping process is performed so that the resulting first epitaxial structures 320 are of the P conductivity type. The P-type first epitaxial structures 320 have a dopant concentration higher than dopant concentration of the P-type first well region 1031. Preferably, the first epitaxial structures 320 contain conductive ions at a concentration greater than or equal to 1.0 e20 cm⁻³. The first patterned mask layer 300 is then stripped away.

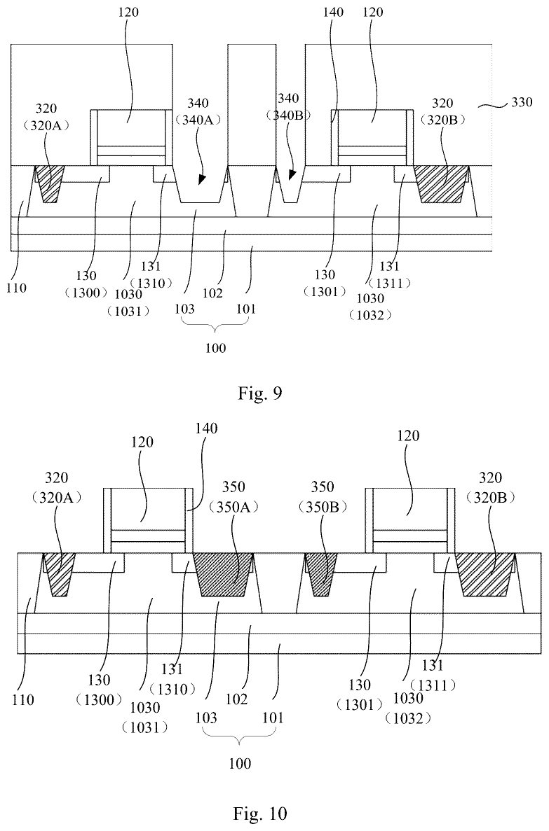

As shown in FIG. 9, according to embodiments of the present application, a second patterned mask layer 330 is then formed over the SOI substrate 100. The second patterned mask layer 330 covers the gate structures 120, the first epitaxial structures 320 and a portion of the SOI substrate 100, leaving a portion of the SOI substrate 100 being exposed.

The exposed SOI substrate 100 is etched to form second openings 340 therein, the second opening extends from the surface of the well region 1030 into the well region 1030. In Embodiment 2, one second opening 340 is formed in the first well region 1031, and another second opening 340 is formed in the second well region 1032, and these second opening 340 are referred to herein respectively as a second opening 340A and a second opening 340B. According to embodiments of the present application, the second opening 340A is adjacent to and connected with the spacer 140 on the corresponding gate structure 120, and the second opening 340B is spaced apart from the spacer 140 on the corresponding gate structure 120.

According to embodiments of the present application, the second openings 340 have the same depth as the first openings 310. Of course, there may be tolerances among the first openings 310, among the second openings 340, and among the first opening 310 and second opening 340. For example, there may be a depth difference between the first and second openings, which is less than 10% or the like of a predetermined depth. The first openings 310 and second openings 340 are spaced at a certain distance from the top surface of the buried oxide layer 102.

Afterwards, as shown in FIG. 10, a second epitaxy process is performed to form second epitaxial structures 350 in the second openings 340. Specifically, a second epitaxial structure 350A is formed in the second opening 340A, and a second epitaxial structure 350B in the second opening 340B. According to embodiments of the present application, concurrently with the second epitaxy process, an N-type doping process is performed so that the resulting second epitaxial structures 350 are of the N conductivity type. The N-type second epitaxial structures 350 have a dopant concentration higher than dopant concentration of the N-type second well region 1032. Preferably, the second epitaxial structures 350 contain conductive ions at a concentration greater than or equal to 1.0 e20 cm⁻³. The second patterned mask layer 330 is then stripped away.

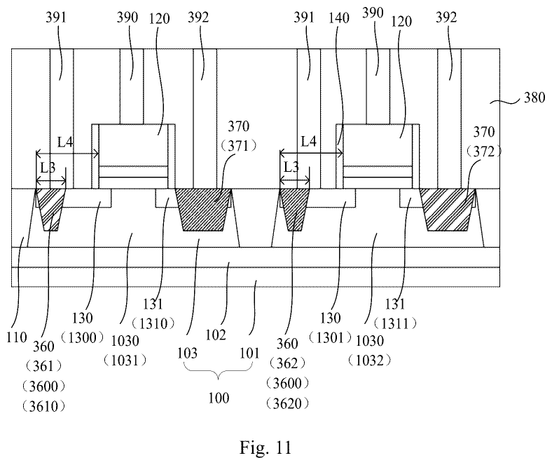

Referring to FIG. 11, according to embodiments of the present application, an annealing process is then performed on the first epitaxial structures 320 and the second epitaxial structures 350 to form sources 360 and drains 370 in the well regions 1030. According to embodiments of the present application, the source 360 consists of only a primary source 3600, which is of the same conductivity type as the (corresponding) well region 1030 and has a higher dopant concentration than the (corresponding) well region 1030.

In Embodiment 2, a first source 361 and a first drain 371 are formed in the first well region 1031, and a second source 362 and a second drain 372 are formed in the second well region 1032. According to embodiments of the present application, the first source 361 consists of only a P-type first primary source 3610, and the second source 362 consists of only an N-type second primary source 3620.

With continued reference to FIG. 11, according to embodiments of the present application, a first side of the primary source 3600 is spaced from a second side of the primary source 3600 at a first distance L3, and a first side of the primary source 3600 is spaced from a third side of the (corresponding) gate structure 120 at a second distance L4. Preferably, the first distance L3 is less than or equal to 0.5 times the second distance L4. The first side is a side of the primary source 3600 far away from the (corresponding) gate structure 120, while the second side is a side of the primary source 2100 proximal to the (corresponding) gate structure 120. The third side is a side of the gate structure 120 proximal to the corresponding source 360. With this arrangement, not only good performance of the resulting transistors can be ensured, but electric charge can also be conducted away from their body regions through the sources 360, avoiding the otherwise possible floating body effect (FBE). Thus, PDSOI transistors with improved quality and reliability can be obtained.

Further, an interlayer dielectric layer 380 is further formed over the SOI substrate 100, which covers the SOI substrate 100 and the gate structures 120. Gate contacts 390, source contacts 391 and drain contacts 392 are then formed in the interlayer dielectric layer 380. The gate contacts 390 are connected to the gate structures 120, the source contacts 391 are connected to the sources360, and the drain contacts 392 are connected to the drains 270. According to embodiments of the present application, the source contacts 391 are also connected to the lightly doped source regions 130.

In embodiments of the present application, there is also provided a corresponding PDSOI transistor. As shown in FIG. 11, the PDSOI transistor includes: an SOI substrate 100 including a bottom silicon layer 101, a buried oxide layer 102 formed on the bottom silicon layer 101 and a top silicon layer 103 formed on the buried oxide layer 102, the top silicon layer 103 formed therein with a well region 1030; a gate structure 120 formed on the SOI substrate 100; and a source 360 and a drain 370, which are located in the well region 1030 on opposite sides of the gate structure 120, the source 360 formed by epitaxy, at least a portion of the source 360 having the same conductivity type as the well region 1030.

According to embodiments of the present application, the source 360 consists of only a primary source 3600, which is of the same conductivity type as the (corresponding) well region 1030 and has a higher dopant concentration than the (corresponding) well region 1030. In Embodiment 2, the source 360 contains conductive ions at a concentration greater than or equal to 1.0 e20 cm⁻³.

The PDSOI transistor further includes a lightly doped source region 130 and a lightly doped drain region 131, each of which extends from the well region 1030 under the gate structure 120 to the well region 1030 beside the gate structure 120. The lightly doped source region 130 and the lightly doped drain region 131 are formed through ion implantation at a dose greater than or equal to 1.0 e15 cm⁻².

The PDSOI transistor further includes: an interlayer dielectric layer 380 which covers both the SOI substrate 100 and the gate structure 120; and a gate contact 390, a source contact 391 and a drain contact 392 formed in the interlayer dielectric layer 380, the gate contact 390 connected to the gate structure 120, the source contact 391 connected to the source 360, the drain contact 392 connected to the drain 370.

With this arrangement, electric charge can be conducted away from the body region through the source 360, avoiding the otherwise possible floating body effect (FBE) and imparting improved quality and reliability to the PDSOI transistor.

The description presented above is merely that of some preferred embodiments of the present invention and is not intended to limit the scope thereof in any sense. Any and all changes and modifications made by those of ordinary skill in the art based on the above teachings fall within the scope of the invention.

1. A partially depleted silicon-on-insulator (PDSOI) transistor, comprising:
a silicon-on-insulator (SOI) substrate comprising a bottom silicon layer, a buried oxide layer formed on the bottom silicon layer and a top silicon layer formed on the buried oxide layer, wherein a well region is formed in the top silicon layer;
a gate structure formed on the SOI substrate; and
a source and a drain, wherein the source and the drain are located in the well region on opposite sides of the gate structure, wherein the source is formed by epitaxy, and wherein at least a portion of the source has a same conductivity type as the well region.

2. The PDSOI transistor of claim 1, wherein the source comprises a primary source, wherein the primary source has a same conductivity type as the well region, and wherein the primary source has a higher dopant concentration than the well region.

3. The PDSOI transistor of claim 2, wherein the source further comprises a secondary source, wherein the primary source and the secondary source are located side by side along an extending direction of the SOI substrate, and wherein the secondary source has a conductivity type different from a conductive type of the well region.

4. The PDSOI transistor of claim 3, wherein the secondary source is closer to the gate structure than the primary source.

5. The PDSOI transistor of claim 2, wherein a first side of the primary source is spaced at a first distance from a second side of the primary source, wherein a first side of the primary source is spaced at a second distance from a third side of the gate structure, wherein the first distance is less than or equal to 0.5 times the second distance, and wherein: the first side is a side of the primary source far away from the gate structure; the second side is a side of the primary source proximal to the gate structure; and the third side is a side of the gate structure proximal to the source.

6. The PDSOI transistor of claim 2, wherein the source contains conductive ions at a concentration greater than or equal to 1.0 e20 cm⁻³.

7. The PDSOI transistor of claim 1, further comprising a lightly doped source region and a lightly doped drain region, wherein each of the lightly doped source region and the lightly doped drain region extends from the well region under the gate structure to the well region beside the gate structure.

8. The PDSOI transistor of claim 7, wherein an ion implantation dosage of each of the lightly doped source region and the lightly doped drain region is greater than or equal to 1.0 e15 cm⁻².

9. The PDSOI transistor of claim 1, further comprising: an interlayer dielectric layer covering each of the SOI substrate and the gate structure; and a gate contact, a source contact and a drain contact formed in the interlayer dielectric layer, wherein: the gate contact is connected to the gate structure; the source contact is connected to the source; and the drain contact is connected to the drain.

10. A method for fabricating a partially depleted silicon-on-insulator (PDSOI) transistor, comprising:
providing a silicon-on-insulator (SOI) substrate, wherein the SOI substrate comprises a bottom silicon layer, a buried oxide layer formed on the bottom silicon layer and a top silicon layer formed on the buried oxide layer, and wherein at least one well region is formed in the top silicon layer;
forming at least one gate structure on the SOI substrate; and
forming at least one source and at least one drain in the SOI substrate by epitaxy, wherein the source and the drain are located in the well region on opposite sides of the gate structure, and wherein at least a portion of the source is of a same conductivity type as the well region.

11. The method for fabricating the PDSOI transistor of claim 10, further comprising: performing an ion implantation process on the at least one well region to form at least one lightly doped source region and at least one lightly doped drain region.

12. The method for fabricating the PDSOI transistor of claim 10, forming at least one source and at least one drain in the SOI substrate by epitaxy, further comprising: forming at least one first opening in the SOI by etching a portion of the SOI substrate with a first patterned mask layer serving as a mask.

13. The method for fabricating the PDSOI transistor of claim 12, after forming the at least one first opening, performing a first epitaxy process to form at least one first epitaxial structure in the at least one first opening.

14. The method for fabricating the PDSOI transistor of claim 13, further comprising: forming at least one second opening in the SOI by etching at least the SOI substrate with a second patterned mask layer serving as a mask.

15. The method for fabricating the PDSOI transistor of claim 14, after forming the at least one second opening, performing a second epitaxy process to form at least one second epitaxial structure in the at least one second opening.

16. The method for fabricating the PDSOI transistor of claim 15, forming at least one source and at least one drain in the SOI substrate by epitaxy, further comprising: performing an annealing process on the at least one first epitaxial structure and the at least one second epitaxial structure.

17. The method for fabricating the PDSOI transistor of claim 10, wherein the source comprises a primary source, wherein the primary source has a same conductivity type as the well region, and wherein the primary source has a higher dopant concentration than the well region.

18. The method for fabricating the PDSOI transistor of claim 17, wherein the source further comprises a secondary source, wherein the primary source and the secondary source are located side by side along an extending direction of the SOI substrate, and wherein the secondary source has a conductivity type different from a conductive type of the well region.
